(19) United States
(12) Patent Application Publication
(10) Pub. No.: US 2026/0305025 A1
(43) Pub. Date: Oct. 1, 2026

(54) LIGHT-EMITTING DEVICE

(71) Applicant: Ennostar Corporation, Hsinchu City (TW)

(72) Inventors: Kai-Hung CHENG, Hsinchu City (TW); Ku-Cheng LIN, Hsinchu City (TW); Chun-Min LIN, Hsinchu City (TW)

(21) Appl. No.: 19/578,540

(22) Filed: Mar. 25, 2026

(30) Foreign Application Priority Data
Mar. 26, 2025 (TW) 114111455

(51) Int. Cl. H10H 20/855; H10H 20/814; H10H 29/14

(52) U.S. Cl. CPC H10H 20/855; H10H 20/814; H10H 29/14

(57) ABSTRACT

A light-emitting device includes a substrate, a light-emitting element, and a lens member. The light-emitting element is disposed on the substrate. The lens member is disposed on the substrate and seals the light-emitting element and includes a central axis, a lower surface, and an upper surface having a central recessed surface, a reflective surface and a convex surface. The central axis is substantially perpendicular to the substrate. The reflective surface is arranged between the central concave surface and the convex surface, and is seamlessly connected to the convex surface at the upper end. The lower surface is arranged above the substrate.

### CROSS REFERENCE TO RELATED APPLICATIONS

This application claims the benefit of Taiwan Patent Application No. 114111455, filed on Mar. 26, 2025, the entirety of which is incorporated by reference herein.

### TECHNICAL FIELD

The present disclosure relates to a light-emitting device, and in particular it relates to a light-emitting device capable of increasing the light-emitting angle.

### BACKGROUND

With the advancement of technology, light-emitting devices incorporating light-emitting diodes have become widely adopted in various products.

In order to obtain a larger light-emitting angle, a light-emitting device is generally provided with an optical lens on the light-emitting diode, and the shape of the optical lens is designed to increase the angle of the light beams emitted from the light-emitting diode. However, the optical lens has a relatively high cost, and additional equipment is also required to correctly install the optical lens on the light-emitting diode, thereby increasing the complexity and the time of the manufacturing process.

Therefore, how to design a light-emitting device that increases the light-emitting angle while reducing the cost is a problem that needs to be solved.

### BACKGROUND

Accordingly, one objective of the present disclosure is to provide a light-emitting device to solve the above problems.

According to some embodiments of the disclosure, a light-emitting device includes a substrate, a light-emitting element, and a lens member. The light-emitting element is disposed on the substrate and configured to emit light. The lens member is disposed on the substrate and seals the light-emitting element. The lens member includes the central axis, which is substantially perpendicular to the substrate. The lens member includes an upper surface and a lower surface. The upper surface has a central recessed surface, a reflective surface, and a convex surface. The reflective surface is arranged between the central recessed surface and the convex surface. The reflective surface is arranged connected to the convex surface at the upper end. The lower surface is arranged above the substrate. When viewed along the first axis (which is perpendicular to the central axis), the central recessed surface has a recess depth measured along the central axis, the light-emitting element has a first height measured along the central axis, and the lens member has a second height measured from the substrate to the upper end in a direction parallel the central axis. The ratio of the second height to the recess depth is between 2.5 and 4.5.

According to some embodiments, the light-emitting element emits light, a portion of the light is emitted through the central recessed surface, and a portion of the light is completely reflected by the reflective surface.

According to some embodiments, a portion of the light is emitted to directly pass through the outer convex surface.

According to some embodiments, when viewed along the first axis, the reflective surface has a first curved portion, the convex surface has a second curved portion, the first curved portion and the second curved portion are continuous curved surfaces, and the first curved portion and the second curved portion are connected at an apex of the upper end.

According to some embodiments, the lens member further has an concave surface which is connected to the convex surface and is located between an inflection portion and the lower surface, and the concave surface is connected to the substrate at a contact portion, wherein when viewed along the first axis, the concave surface has a third curved portion, the third curved portion is connected to the second curved portion at an inflection point of the inflection portion, and the third curved portion is connected to the substrate at a contact point of the contact portion.

According to some embodiments, the light-emitting element has a central point passed by the central axis, the central point and the apex define a first connecting line, a first included angle is formed between the first connecting line and the central axis, and the first included angle is less than or equal to 42.5 degrees.

According to some embodiments, the central point and the inflection point define a second connecting line, a second included angle is formed between the second connecting line and the central axis, and the second included angle is greater than 42.5 degrees and less than or equal to 80 degrees.

According to some embodiments, when viewed along the first axis, the central point forms a projection point on the third curved portion along a second axis, and the second axis is perpendicular to the first axis, wherein the central point and the projection point define a third connecting line, a third included angle is formed between the third connecting line and the central axis, and the third included angle is greater than 80 degrees and less than or equal to 90 degrees.

According to some embodiments, when viewed along the central axis, the contact portion has a first circular structure, and the upper end has a second circular structure, wherein the first circular structure has a first diameter, the second circular structure has a second diameter, and the first diameter is greater than the second diameter.

According to some embodiments, the light-emitting element has a width on a second axis, and the second diameter is greater than the width, wherein the second axis is perpendicular to the first axis, and the ratio of the first diameter to the width is from 12 to 14.

According to some embodiments, when viewed along the central axis, the central recessed surface has a third circular structure, the third circular structure has a third diameter, and the width is greater than the third diameter.

According to some embodiments, the reflective surface intersects the central recessed surface at a central peripheral portion, and when viewed along the first axis, the first curved portion has a curvature decreasing from a peripheral point of the central peripheral portion to the apex.

According to some embodiments, when viewed along the first axis, the second curved portion has a curvature decreasing from the inflection point to the apex.

According to some embodiments, when viewed along the first axis, the third curved portion has a curvature which decreases to 0 from the inflection point to the contact point.

According to some embodiments, the third curved portion has a first curved segment and a second curved segment, and when viewed along a second axis, the light-emitting element overlaps the second curved segment without overlapping the first curved segment, wherein the second axis is perpendicular to the first axis.

According to some embodiments, a portion of the light is emitted through the second curved segment.

According to some embodiments, when viewed along the first axis, the first curved portion is asymmetrical with respect to the second curved portion.

According to some embodiments, the recess depth is greater than the first height, and the ratio of the second height to the first height is between 7.8 and 10.

The present disclosure provides a light-emitting device, including a substrate, a light-emitting element, and a lens member. The light-emitting element is disposed on the substrate and the lens member seals the light-emitting element. The lens member may have a central recessed surface, a reflective surface, a convex surface, and a concave surface. The central recessed surface is a planar surface, and the reflective surface is a curved surface and is connected to the central recessed surface at a central peripheral portion.

The reflective surface and the convex surface are continuous curved surfaces, and the reflective surface and the convex surface are connected to the upper end. The concave surface and the convex surface are continuously connected to an inflection portion, and a portion of the concave surface contacts the substrate. The lens member is formed as an integrated optical lens, the light-emitting element directly contacts the lens member and is completely encapsulated within the lens member, and there is no gap between the light-emitting element and the lens member. Based on the configuration of the lens member and the light-emitting element of the present disclosure, the light-emitting angle of the light-emitting device can be effectively improved to achieve a light-emitting effect with a wider light distribution.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion. The patent or application file contains at least one drawing executed in color. Copies of this patent or patent application publication with color drawings will be provided by the Office upon request and payment of the necessary fee.

FIG. 1 is a stereoscopic view of a light-emitting module 10 according to an embodiment of the present disclosure.

FIG. 2 is a stereoscopic view of a lens member 106 according to an embodiment of the present disclosure;

FIG. 3A is a cross-sectional view of a light-emitting device 100 along line segment A-A in FIG. 1 according to an embodiment of the present disclosure;

FIG. 3B is an enlarged cross-sectional view of a light-emitting element 104 according to an embodiment of the present disclosure;

FIG. 3C is an enlarged cross-sectional view of the light-emitting element 104 according to another embodiment of the present disclosure;

FIG. 4 is a schematic diagram of the change in the tangent angle of the reflective surface 110 according to an embodiment of the present disclosure;

FIG. 5 is a schematic diagram of the change of the tangent angle of the convex surface 112 according to an embodiment of the present disclosure;

FIG. 6 is a schematic diagram of the change of the tangent angle of the concave surface 116 according to an embodiment of the present disclosure;

FIG. 7 is a schematic diagram of the paths of the light emitted from the light-emitting element 104 according to an embodiment of the present disclosure;

FIG. 8A is a schematic diagram of the light-emitting angle of a conventional light-emitting diode;

FIG. 8B is a schematic diagram of the light-emitting angle of a conventional light-emitting device (with a lens);

FIG. 8C is a schematic diagram of the light-emitting angle of the light-emitting device 100 according to an embodiment of the present disclosure;

FIG. 9A is a color schematic diagram of the illuminance of a conventional light-emitting diode;

FIG. 9B is a color schematic diagram of the illuminance of a conventional light-emitting device (with a lens);

FIG. 9C is a color schematic diagram of the illuminance of the light-emitting device 100 according to an embodiment of the present disclosure;

FIG. 10A is an illuminance distribution diagram of a conventional light-emitting diode in the X-axis direction;

FIG. 10B is an illuminance distribution diagram of a conventional light-emitting device (with a lens) in the X-axis direction;

FIG. 10C is an illuminance distribution diagram of the light-emitting device 100 in the X-axis direction according to an embodiment of the present disclosure;

FIG. 11A is a schematic diagram showing the proportion of different light spot sizes under the condition of 10% of the maximum illuminance;

FIG. 11B is a schematic diagram showing the proportion of different light spot sizes under the condition of 50% of the maximum illuminance; and

FIG. 11C is a schematic diagram showing the proportion of different light spot sizes under the condition of 90% of the maximum illuminance.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are in direct contact, and may also include embodiments in which additional features may be disposed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are in direct contact, and may also include embodiments in which additional features may be disposed interposing the features, such that the features may not be in direct contact. In addition, spatially relative terms, for example, “vertical,” “above,” “over,” “below,”, “bottom,” etc. as well as derivatives thereof (e.g., “downwardly,” “upwardly,” etc.) are used in the present disclosure for ease of description of one feature's relationship to another feature. The spatially relative terms are intended to cover different orientations of the device, including the features.

Unless defined otherwise, all technical and scientific terms used herein have the same meaning as commonly understood by one of ordinary skill in the art to which this disclosure belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

In addition, in some embodiments of the present disclosure, terms concerning attachments, coupling and the like, such as “connected” and “interconnected”, refer to a relationship wherein structures are secured or attached to one another either directly or indirectly through intervening structures, as well as both movable or rigid attachments or relationships, unless expressly described otherwise.

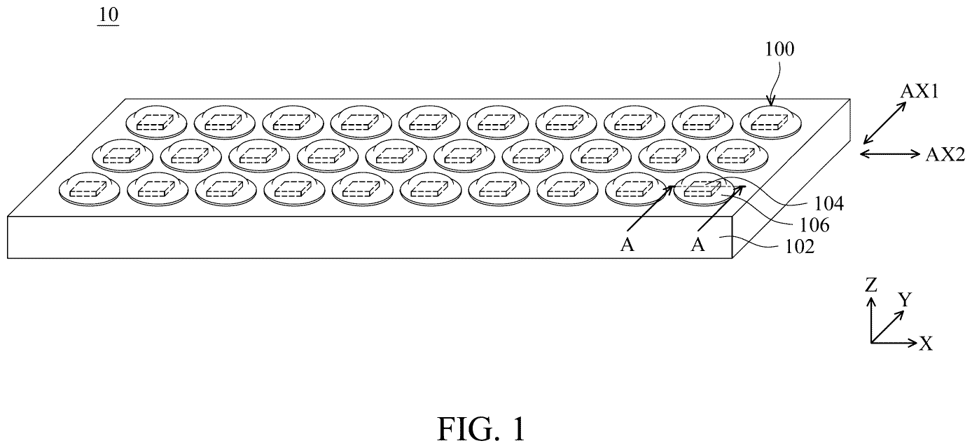

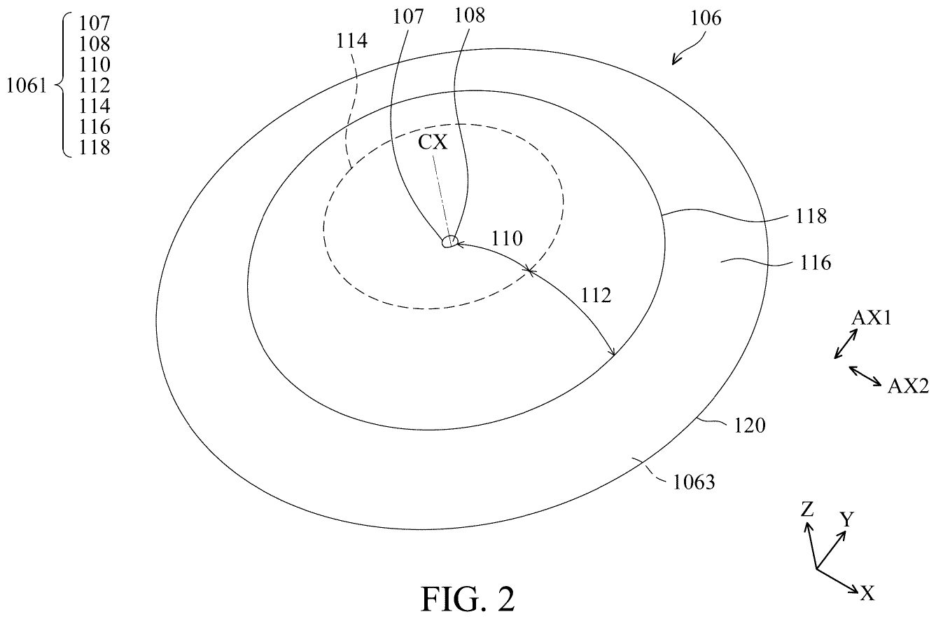

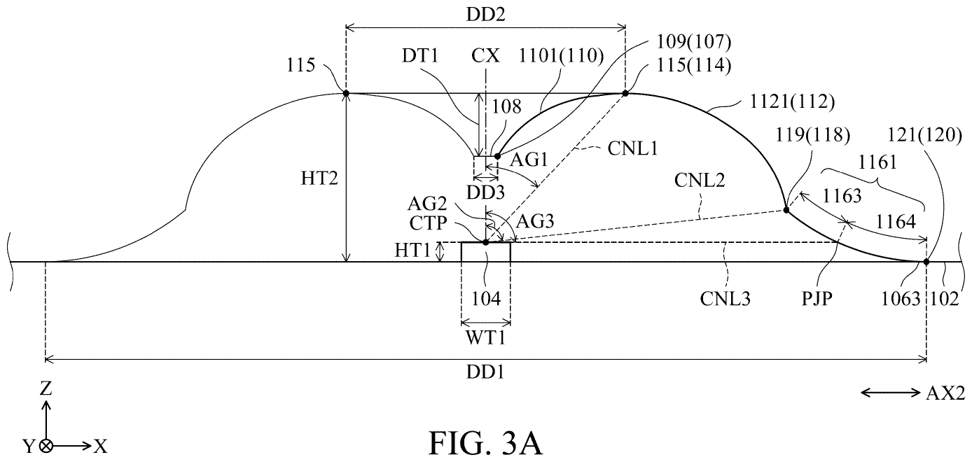

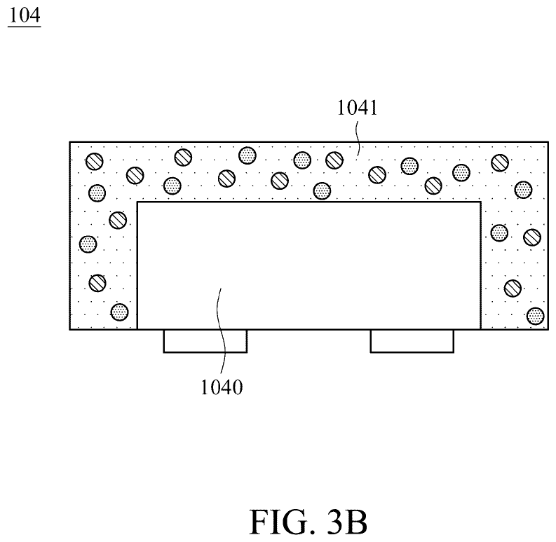

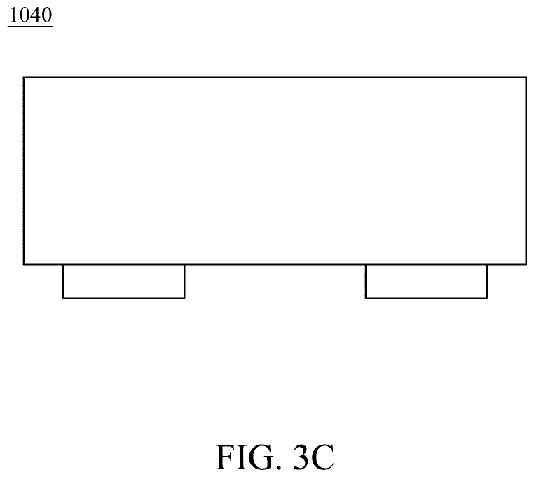

Refer to FIG. 1 to FIG. 3C. FIG. 1 is a stereoscopic view of a light-emitting module 10 including a light-emitting device 100 according to an embodiment of the present disclosure, FIG. 2 is a stereoscopic view of a lens member 106 according to an embodiment of the present disclosure, FIG. 3A is a cross-sectional view of the light-emitting device 100 along line segment A-A in FIG. 1 according to an embodiment of the present disclosure, FIG. 3B is an enlarged cross-sectional view of a light-emitting element 104 according to an embodiment of the present disclosure, and FIG. 3C is an enlarged cross-sectional view of the light-emitting element 104 according to another embodiment of the present disclosure. As shown in FIG. 1, the light-emitting module 10 may include a substrate 102 and a plurality of light-emitting devices 100, and the light-emitting devices 100 are located on the substrate 102. Each light-emitting device includes a light-emitting element 104 and a lens member 106.

These light-emitting elements 104 are disposed on the substrate 102 and configured to emit light, and these light-emitting elements 104 can be, for example, light-emitting diode chips, light-emitting diode packages (LED packages) or chip-scale package LEDs (CSP LED), but they are not limited thereto. The lens member 106 can be a light-transmitting element, such as an optical lens, which is disposed on the substrate 102 and seals the light-emitting element 104. That is, the lens member 106 is in full contact with the light-emitting element 104, and there is no gap between the light-emitting element 104 and the lens member 106. In some embodiments, the manufacturing method of the lens member 106 is through compression molding, and the appearance shape of each lens member 106 is controlled to be consistent. In some embodiments, a transparent material such as polymethyl methacrylate (PMMA), polycarbonate (PC) or polyethylene terephthalate (PET) is molded into a molded optical lens. In addition, the light-emitting element 104 is directly sealed during the lens molding process.

As shown in FIG. 2, the lens member 106 may include an upper surface 1061 and a lower surface 1063. The upper surface 1061 may have a central recessed surface 108, a reflective surface 110 and a convex surface 112. As shown in FIG. 2 and FIG. 3A, the central recessed surface 108 is a planar surface, the reflective surface 110 is arranged between the central recessed surface 108 and the convex surface 112, and seamlessly continuously connected to the convex surface 112 at an upper end 114. The central recessed surface 108 is used to allow at least a portion of the light emitted from the light-emitting element 104 to pass through.

In this embodiment, the lower surface 1063 is arranged above the substrate 102. As shown in FIG. 2 and FIG. 3A, the surface of the lens member 106 that contacts the substrate 102 is the lower surface 1063.

As shown in FIG. 3A, the lens member 106 can define a central axis CX, which is substantially perpendicular to the substrate 102, and when viewed along a first axis AX1 (the Y-axis) that is perpendicular to the central axis CX, the central recessed surface 108 has a recess depth DT1 measured along the central axis CX.

Furthermore, the light-emitting element 104 has a first height HT1 measured in the direction of the central axis CX, and the lens member 106 has a second height HT2 measured from the substrate 102 to the upper end 115 in a direction parallel the central axis (the Z-axis). The ratio of the second height HT2 to the recess depth DT1 is between 2.5 and 4.5.

In addition, the recess depth DT1 is greater than the first height HT1, and the ratio of the second height HT2 to the first height HT1 is between 7.8 and 10.

As shown in FIG. 3A, when viewed along the first axis AX1, the reflective surface 110 has a first curved portion 1101, the convex surface 112 has a second curved portion 1121, and the first curved portion 1101 and the second curved portion 1121 are continuous curved surfaces.

Specifically, the first curved portion 1101 and the second curved portion 1121 are connected at an apex 115 of the upper end 114. It is worth noting that when viewed along the first axis AX1, relative to a vertical axis passing through the apex 115 to the substrate 102, the first curved portion 1101 is asymmetric with respect to the second curved portion 1121. For example, when viewed along the first axis AX1, the arc length of the first curved portion 1101 is smaller than the arc length of the second curved portion 1121.

Refer to FIG. 2 and FIG. 3A. In this embodiment, the lens member 106 may further have a concave surface 116 arranged the convex surface 112 and the lower surface 1063, and the concave surface 116 is connected to the substrate 102 at a contact portion 120.

As shown in FIG. 3A, when viewed along the first axis AX1, the concave surface 116 has a third curved portion 1161, and the third curved portion 1161 is connected to the second curved portion 1121 at an inflection point 119 positioned between the convex surface 112 and the concave surface 116, and the third curved portion 1161 is connected to the substrate 102 at a contact point 121 of the contact portion 120.

The third curved portion 1161 has a first curved segment 1163 and a second curved segment 1164. When viewed along a second axis AX2, the second axis AX2 being a horizontal axis, the light-emitting element 104 overlaps the second curved segment 1164 without overlapping with the first curved segment 1163. The second axis AX2 is perpendicular to the first axis AX1.

As shown in FIG. 3A, the light-emitting element 104 can define a central point CTP, and the central axis CX passes through the central point CTP. The central point CTP and the apex 115 can define a first connecting line CNL1, a first included angle AG1 is formed between the first connecting line CNL1 and the central axis CX, and the first included angle AG1 is less than or equal to 42.5 degrees.

Similarly, as shown in FIG. 3A, the central point CTP and the inflection point 119 can define a second connecting line CNL2, a second included angle AG2 is formed between the second connecting line CNL2 and the central axis CX, and the second included angle AG2 is greater than 42.5 degrees and less than or equal to 80 degrees.

Furthermore, as shown in FIG. 3A, when viewed along the first axis AX1, the central point CTP forms a projection point PJP on the third curved portion 1161 along the direction of the second axis AX2, and the first curved segment 1163 and the second curved segment 1164 are connected at the projection point PJP.

Similarly, the central point CTP and the projection point PJP may define a third connecting line CNL3, a third included angle AG3 is formed between the third connecting line CNL3 and the central axis CX, and the third included angle AG3 is greater than 80 degrees and less than or equal to 90 degrees.

Furthermore, as shown in FIG. 2, when viewed along the central axis CX, the contact portion 120 has a first circular structure, and the upper end 114 has a second circular structure. As shown in FIG. 3A, the first circular structure has a first diameter DD1, the second circular structure has a second diameter DD2, and the first diameter DD1 is greater than the second diameter DD2.

The light-emitting element 104 has a width WT1 in the second axis AX2, the second axis being a horizontal axis. The second diameter DD2 is greater than the width WT1, and the ratio of the first diameter DD1 to the width WT1 is from 12 to 14.

In this embodiment, the reflective surface 110 and the central recessed surface 108 are connected at a central peripheral portion 107. As shown in FIG. 2 and FIG. 3A, when viewed along the central axis CX, the central recessed surface 108 is defined by the central peripheral portion 107, and the central recessed surface 108 has a third circular structure. The third circular structure has a third diameter DD3, and the width WT1 of the light-emitting element 104 is greater than the third diameter DD3.

As shown in FIG. 3B, the light-emitting element 104 includes a solid-state semiconductor light source 1040 and a wavelength conversion portion 1041. In some embodiments, the solid-state semiconductor light source 1040 may be a flip-chip blue light emitting diode chip or a UV light emitting diode chip. In some embodiments, the light-emitting element 104 may be a chip-scale package (CSP), and the wavelength conversion portion 1041 is conformally formed on the surface of the LED chip (the solid-state semiconductor light source 1040) so as to cover its top surface and side surfaces. In some embodiments, the LED chip may be a sub-millimeter light-emitting diode (mini-LED) chip or a micro-LED chip. In an embodiment where the light-emitting element 104 emits white light, the solid-state semiconductor light source 1040 may be a blue light-emitting diode chip configured to emit blue light, and the wavelength conversion portion 1041 includes a mixture of a red light conversion material and a green light conversion material. The red and green light conversion materials respectively absorb part of the blue light and emit red light and green light, and the red light, green light, and the remaining blue light are mixed to form white light. In another embodiment where the light-emitting device emits white light, when the solid-state semiconductor light source 1040 is a UV light-emitting diode chip, the wavelength conversion portion 1041 includes a mixture of a blue light conversion material, a red light conversion material, and a green light conversion material. The blue light conversion material, the red light conversion material, and the green light conversion material absorb part of the ultraviolet light and respectively emit blue light, red light, and green light, and then the blue, red, and green lights are mixed to form white light. In addition, the red light conversion material may include red quantum dots or red phosphors, and the red phosphors may be, for example, (Sr, Ca)AlSiN₃:Eu²⁺, Ca₂Si₅N₈:Eu²⁺, Sr(LiAl₃N₄):Eu²⁺, or manganese-doped red fluoride phosphors (such as K₂GeF₆:Mn⁴⁺, K₂SiF₆:Mn⁴⁺, K₂TiF₆:Mn⁴⁺), but the present disclosure is not limited thereto. The blue light conversion material may be blue quantum dots or blue phosphors, but the present disclosure is not limited thereto. The green light conversion material may include green quantum dots or green phosphors, and the green phosphors may be, for example, lutetium aluminum garnet (LuAG) phosphors, yttrium aluminum garnet (YAG) phosphors, sialon (β-SiAlON) phosphors, or silicate phosphors, but the present disclosure is not limited thereto.

In some embodiments, the quantum dots may be cadmium-based quantum dots, such as one or more of cadmium sulfide (CdS) quantum dots, cadmium selenide (CdSe) quantum dots, cadmium telluride (CdTe) quantum dots, cadmium sulfide/zinc sulfide (CdS/ZnS) quantum dots, or cadmium selenide/zinc sulfide (CdSe/ZnS) quantum dots. Alternatively, the quantum dots may be alloy-structure quantum dots having cadmium sulfide (CdS), cadmium selenide (CdSe), or cadmium telluride (CdTe) as the core, or core-shell-structure quantum dots having cadmium sulfide (CdS), cadmium selenide (CdSe), or cadmium telluride (CdTe) as the core, but the present disclosure is not limited thereto.

In some embodiments, the quantum dots may be cadmium-free quantum dots, such as zinc selenide (ZnSe) quantum dots, indium phosphide (InP) quantum dots, lead sulfide (PbS) quantum dots, copper indium sulfide (CuInS2) quantum dots, zinc oxide (ZnO) quantum dots, or perovskite quantum dots (such as CsPbCl₃ quantum dots, CsPbBr₃ quantum dots, CsPbI₃ quantum dots), but the present disclosure is not limited thereto.

As shown in FIG. 3C, the light-emitting element 104 includes the aforementioned solid-state semiconductor light source 1040. In some embodiments, the solid-state semiconductor light source 1040 may be a light-emitting diode chip, such as a blue LED chip, a green LED chip, or a red LED chip. For ease of explanation, FIG. 3C uses a flip-chip blue LED chip for illustration, but the present disclosure is not limited thereto.

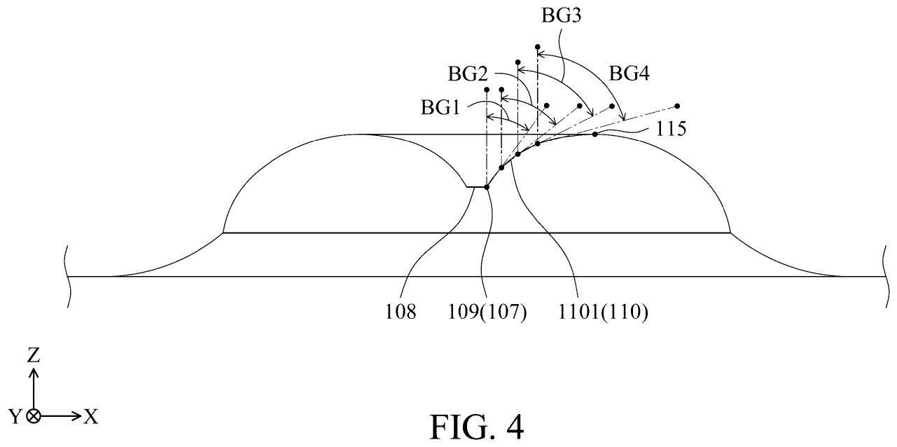

Refer to FIG. 2 and FIG. 4. FIG. 4 is a schematic diagram of the change in the tangent angle of the reflective surface 110 according to an embodiment of the present disclosure. When viewed along the first axis AX1, from a peripheral point 109 of the central peripheral portion 107 to the apex 115, the first curved portion 1101 may form a plurality of tangents, and the angles of the included angles BG1 to BG4 formed between these tangents and the Z-axis gradually increase.

For example, the included angle BG1 is 35 degrees, the included angle BG2 is 51 degrees, the included angle BG3 is 62 degrees, and the included angle BG4 is 74 degrees, but they are not limited thereto. That is, the first curved portion 1101 has a curvature gradually decreasing from the peripheral point 109 to the apex 115.

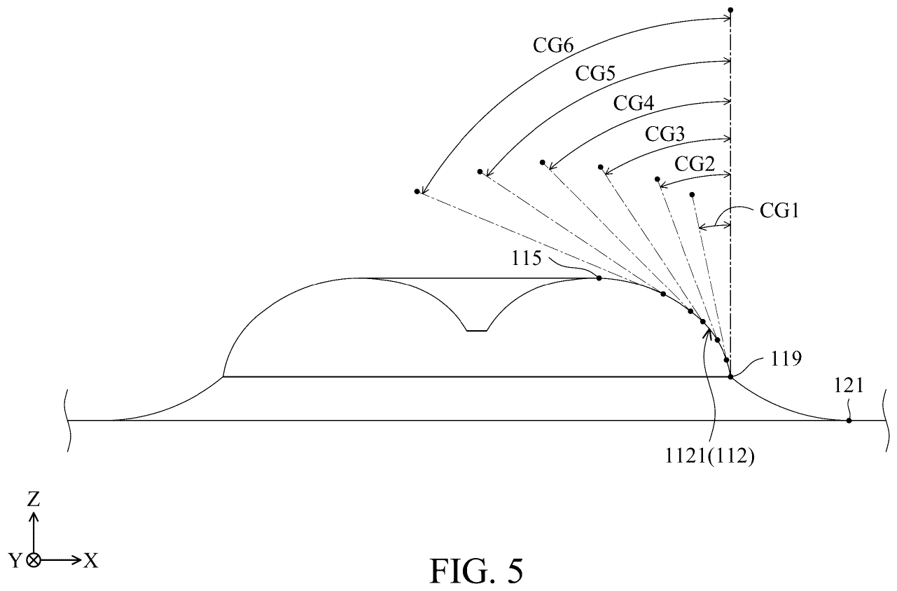

Refer to FIG. 5. FIG. 5 is a schematic diagram of the change of the tangent angle of the convex surface 112 according to an embodiment of the present disclosure. In this embodiment, when viewed along the first axis AX1, within the range from the inflection point 119 to the apex 115, the second curved portion 1121 can form a plurality of tangents, and the angles of the included angles CG1 to CG6 formed between these tangents and the Z-axis gradually increase.

For example, the included angle CG1 is 11 degrees, the included angle CG2 is 20 degrees, the included angle CG3 is 33 degrees, the included angle CG4 is 45 degrees, the included angle CG5 is 56 degrees, and the included angle CG6 is 67 degrees, but they are not limited thereto. That is, the second curved portion 1121 has a curvature gradually decreasing from the inflection point 119 to the apex 115.

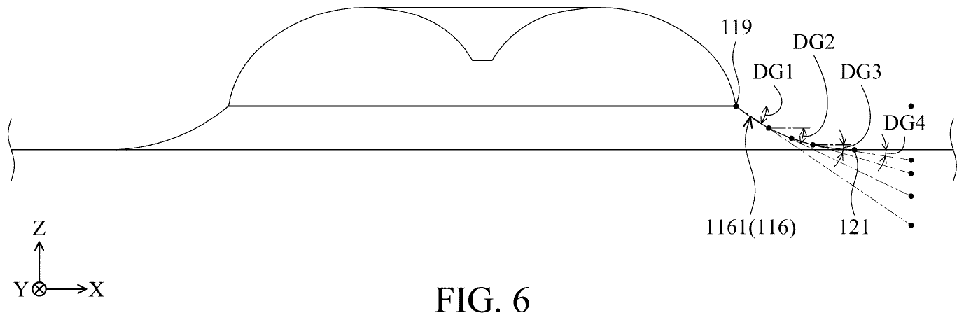

Refer to FIG. 6. FIG. 6 is a schematic diagram of the change of the tangent angle of the concave surface 116 according to an embodiment of the present disclosure. In this embodiment, when viewed along the first axis AX1, in the range from the inflection point 119 to the contact point 121, the third curved portion 1161 can form a plurality of tangents, and the angles of the included angles DG1 to DG4 formed between these tangents and the X-axis gradually decrease.

For example, the included angle DG1 is 34 degrees, the included angle DG2 is 25 degrees, the included angle DG3 is 16 degrees, and the included angle DG4 is 9 degrees, but they are not limited thereto. That is, the curvature of the third curved portion 1161 from the inflection point 119 to the contact point 121 gradually decreases to 0.

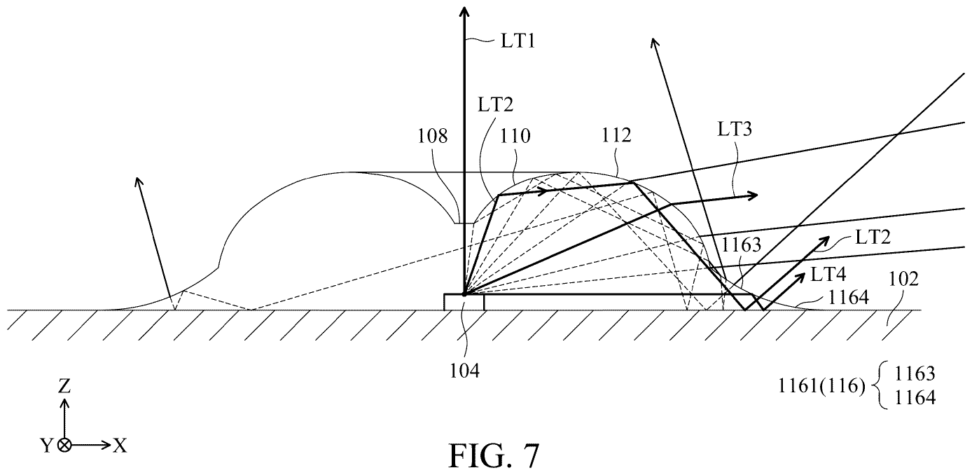

Refer to FIG. 2 and FIG. 7. FIG. 7 is a schematic diagram of the paths of a portion the light emitted from the light-emitting element 104 according to an embodiment of the present disclosure. As shown in FIG. 7, the light-emitting element 104 is configured to emit light having a plurality of beams, and a portion of these beams are emitted through the central recessed surface 108. Specifically, as shown in FIG. 7, the first beam LT1 emitted by the light-emitting element 104 can directly pass through the central recessed surface 108 to emit light.

Furthermore, a portion of these beams are reflected by the reflective surface 110 to the convex surface 112 and then emitted through the convex surface 112. Specifically, as shown in FIG. 7, a second beam LT2 emitted by the light-emitting element 104 is emitted to the reflective surface 110 and then totally reflected by the reflective surface 110.

It is worth noting that the totally reflected second beam LT2 is not emitted from the convex surface 112. As shown in FIG. 7, the second beam LT2 is reflected from the reflective surface 110 to the convex surface 112, and then is reflected by the convex surface 112 to the substrate 102. Finally, the substrate 102 reflects the second beam LT2 again and then to be emitted through the second curved segment 1164.

In addition, a portion of these beams are refracted directly through the convex surface 112. Specifically, as shown in FIG. 7, a third beam LT3 emitted by the light-emitting element 104 is emitted directly through the convex surface 112 and is refracted after passing through the convex surface 112.

In addition, a portion of these beams are reflected by the second curved segment 1164 and the substrate 102 and then emitted from the second curved segment 1164. Specifically, as shown in FIG. 7, a fourth beam LT4 emitted by the light-emitting element 104 is sequentially reflected by the second curved segment 1164 and the substrate 102 and then emitted from the second curved segment 1164.

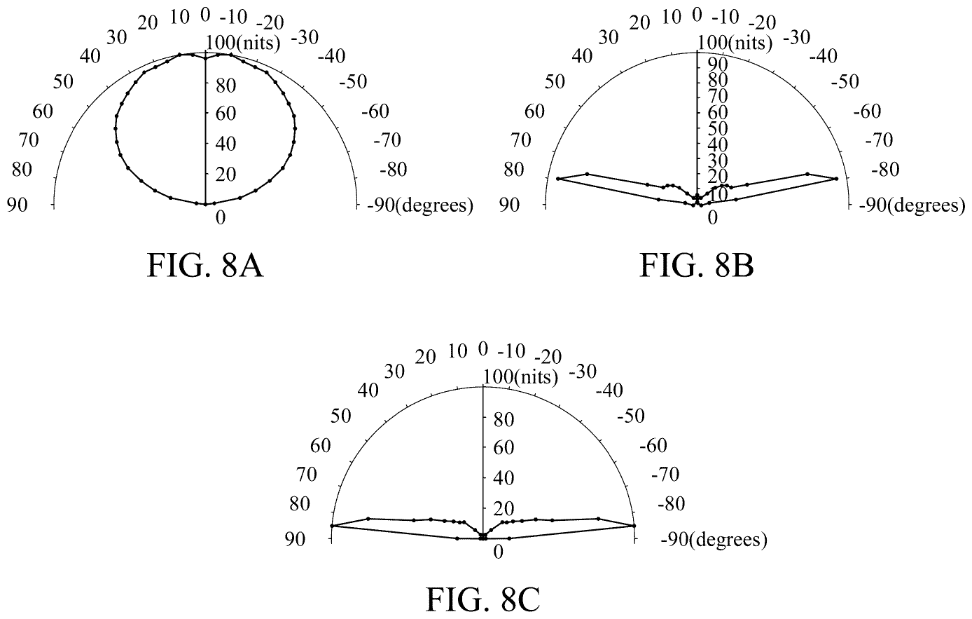

Next, refer to FIG. 8A to FIG. 8C. FIG. 8A is a schematic diagram of the light-emitting angle of a conventional light-emitting diode, FIG. 8B is a schematic diagram of the light-emitting angle of a conventional light-emitting device (with a lens), and FIG. 8C is a schematic diagram of the light-emitting angle of the light-emitting device 100 according to an embodiment of the present disclosure. The origin 0 is the position of the light-emitting diode (such as the light-emitting element 104).

As can be seen from FIG. 8A, the light-emitting angle of the light-emitting diode without a lens is only between +65 degrees and −65 degrees, while as shown in FIG. 8B, the light-emitting angle of the conventional light-emitting device with a lens is between +80 degrees and −80 degrees at most. As shown in FIG. 8C, the light-emitting angle of the light-emitting device 100 of the present disclosure can be between +85 degrees and −85 degrees.

Therefore, it can be seen that based on the configuration of the lens member 106 and the light-emitting element 104 of the present disclosure, the light-emitting angle of the light-emitting device 100 can be effectively improved to achieve a large light angle batwing light distribution characteristic, and increase the wide light emitting effect, which helps the light-emitting device to be applied to a thinner light-emitting module.

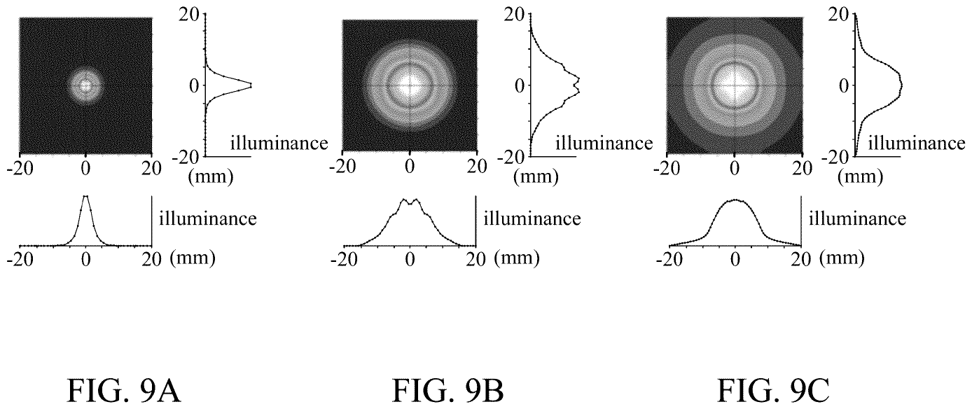

Next, refer to FIG. 9A to FIG. 9C. FIG. 9A is a color schematic diagram of the illuminance of a conventional light-emitting diode, FIG. 9B is a color schematic diagram of the illuminance of a conventional light-emitting device (with a lens), and FIG. 9C is a color schematic diagram of the illuminance of the light-emitting device 100 according to an embodiment of the present disclosure.

In FIG. 9A, the coordinate (0,0) is the position where the light-emitting element is placed, and the illuminance distribution diagram on the lower side is the illuminance distribution in the X-axis direction (horizontal direction), and the illuminance distribution diagram on the right side is the illuminance distribution in the Y-axis direction (vertical direction), and FIG. 9B and FIG. 9C have the same illuminance distribution diagrams in the X-axis and in the Y-axis.

As can be seen from FIG. 9A, the light emitted by the light-emitting diode without a lens is concentrated in the central position, while as shown in FIG. 9B, the light emitted by the conventional light-emitting device with a lens is more expanded, but cannot reach the edge.

As for the configuration of the present disclosure, as shown in FIG. 9C, the angle range of the light emitted by the light-emitting device 100 of the present disclosure can be further expanded so as to achieve a better lighting effect.

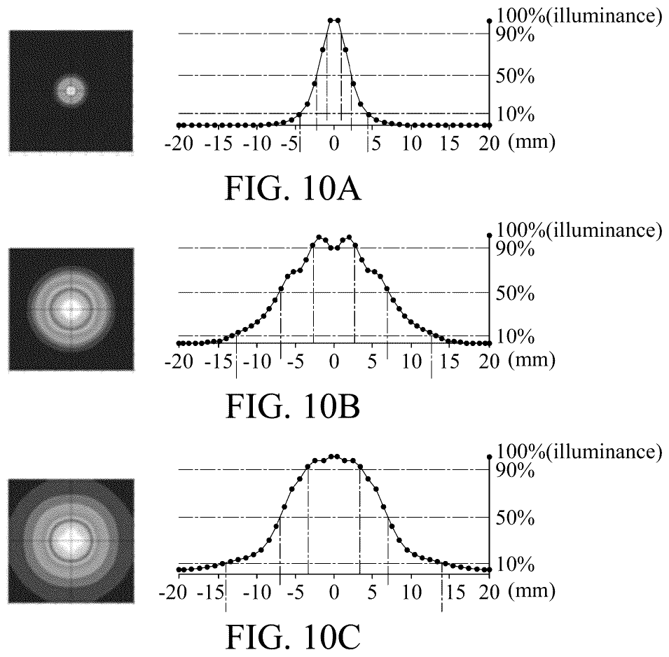

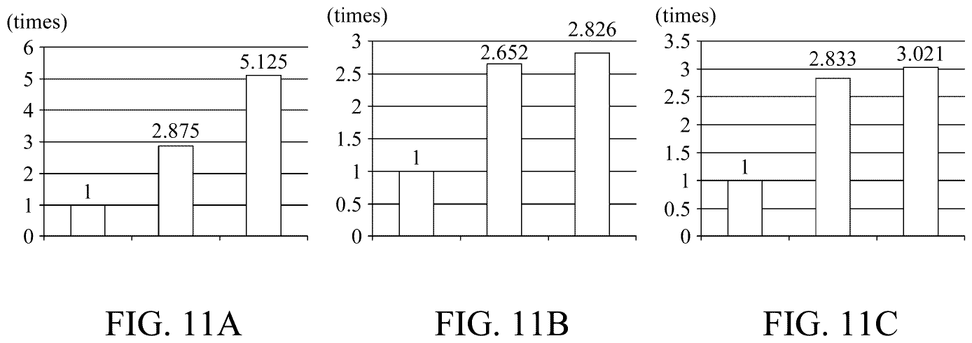

Refer to FIG. 10A to FIG. 10C and FIG. 11A to FIG. 11C. FIG. 10A is an illuminance distribution diagram of a conventional light-emitting diode in the X-axis direction, FIG. 10B is an illuminance distribution diagram of a conventional light-emitting device (with a lens) in the X-axis direction, and FIG. 10C is an illuminance distribution diagram of the light-emitting device 100 in the X-axis direction according to an embodiment of the present disclosure. FIG. 11A is a schematic diagram showing the proportion of different light spot sizes under the condition of 10% of the maximum illuminance, FIG. 11B is a schematic diagram showing the proportion of different light spot sizes under the condition of 50% of the maximum illuminance, and FIG. 11C is a schematic diagram showing the proportion of different light spot sizes under the condition of 90% of the maximum illuminance.

For example, as shown in FIG. 10A to FIG. 10C and FIG. 11A, under the condition of 10% of the maximum illuminance, the spot diameter of the conventional light-emitting diode is, for example, about 9.6 mm, the spot diameter of the conventional light-emitting device with a lens is, for example, about 27.6 mm, and the spot diameter of the light-emitting device 100 of the present disclosure is, for example, about 49.2 mm.

Therefore, as shown in FIG. 11A, the spot diameter of the conventional light-emitting device with a lens is 2.875 times the spot diameter of the pure light-emitting diode, while the spot diameter of the light-emitting device 100 of the present disclosure is 5.125 times the spot diameter of the pure light-emitting diode.

Similarly, as shown in FIG. 11B, under the condition of 50% of the maximum illuminance, the spot diameter of the conventional light-emitting device with a lens is 2.652 times the spot diameter of a pure light-emitting diode, while the spot diameter of the light-emitting device 100 of the present disclosure is 2.826 times the spot diameter of a pure light-emitting diode.

Similarly, as shown in FIG. 11C, under the condition of 90% of the maximum illuminance, the spot diameter of the conventional light-emitting diode is 2.833 times the spot diameter of a pure light-emitting diode, while the spot diameter of the light-emitting device 100 of the present disclosure is 3.021 times the spot diameter of a pure light-emitting diode.

Therefore, it can be seen from FIG. 11A to FIG. 11C that, regardless of any illuminance conditions, the diameter of the light spot of the light-emitting device 100 of the present disclosure is larger than the diameter of the light spot of the conventional light-emitting device. That is, the range of light emitted by the light-emitting device 100 of the present disclosure can be larger and more uniform, so as to achieve a better lighting effect.

In conclusion, the present disclosure provides a light-emitting device 100, including a substrate 102, a light-emitting element 104, and a lens member 106. The light-emitting element 104 is disposed on the substrate 102, and the lens member 106 seals the light-emitting element 104. The lens member 106 may have a central recessed surface 108, a reflective surface 110, a convex surface 112, and a concave surface 116. The central recessed surface 108 is a planar surface, and the reflective surface 110 is a curved surface and is connected to the central recessed surface 108 at a central peripheral portion 107.

The reflective surface 110 and the convex surface 112 are a continuous curved surface, and the reflective surface 110 and the convex surface 112 are connected to an upper end 114. The concave surface 116 and the convex surface 112 are continuously connected to an inflection portion 118, and a portion of the concave surface 116 contacts the substrate 102. The lens member 106 is formed as an integrated optical lens, the light-emitting element 104 directly contacts the lens member 106 and is completely encapsulated within the lens member 106, and there is no gap between the light-emitting element 104 and the lens member 106. Based on the configuration of the lens member 106 and the light-emitting element 104 of the present disclosure, the light-emitting angle of the light-emitting device 100 can be effectively improved to achieve a light-emitting effect with a wider light distribution.

Although the embodiments and their advantages have been described in detail, it should be understood that various changes, substitutions, and alterations can be made herein without departing from the spirit and scope of the embodiments as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein can be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A light-emitting device, comprising:
a substrate;
a light-emitting element, disposed on the substrate; and
a lens member, disposed on the substrate and sealing the light-emitting element, and including a central axis, a lower surface, and an upper surface having a central recessed surface, a reflective surface and a convex surface,
wherein, the central axis is substantially perpendicular to the substrate;
wherein, the reflective surface is arranged between the central recessed surface and the convex surface, and seamlessly connected to the convex surface at an upper end, and the lower surface is arranged above the substrate;
wherein, the central recessed surface has a recess depth measured along the central axis, the light-emitting element has a first height measured along the central axis, the lens member has a second height measured from the substrate to the upper end in a direction parallel the central axis, a ratio of the second height to the recess depth is between 2.5 and 4.5.

2. The light-emitting device of claim 1, wherein, the light-emitting element is configured to emit light, the light has a first beam passing through the central recessed surface and a second beam reflected by the reflective surface.

3. The light-emitting device of claim 2, wherein, the light has a third beam passing through the convex surface.

4. The light-emitting device of claim 3, wherein, in a cross-sectional view, the reflective surface has a first curved portion, and the convex surface has a second curved portion; the first curved portion and the second curved portion are connected at an apex of the upper end.

5. The light-emitting device of claim 4, wherein, the lens member further has a concave surface arranged between the convex surface and the lower surface, in the cross-sectional view, the concave surface is connected to the substrate at a contact portion, and has a third curved portion connected to the second curved portion at an inflection point positioned between the convex surface and the concave surface.

6. The light-emitting device of claim 5, wherein, the light-emitting element has a central point passed by the central axis, the central point and the apex define a first connecting line, a first included angle is formed between the first connecting line and the central axis, and the first included angle is less than or equal to 42.5 degrees.

7. The light-emitting device of claim 6, wherein, the central point and the inflection point define a second connecting line, a second included angle is formed between the second connecting line and the central axis, and the second included angle is greater than 42.5 degrees and less than or equal to 80 degrees.

8. The light-emitting device of claim 7, wherein, the central point forms a projection point on the third curved portion in a horizontal axis, the central point and the projection point define a third connecting line, a third included angle is formed between the third connecting line and the central axis, and the third included angle is greater than 80 degrees and less than or equal to 90 degrees.

9. The light-emitting device of claim 5, wherein, the contact portion has a first circular structure, and the upper end has a second circular structure, the first circular structure has a first diameter, the second circular structure has a second diameter, and the first diameter is greater than the second diameter.

10. The light-emitting device of claim 9, wherein, the light-emitting element has a width in a horizontal axis, and the second diameter is greater than the width, and a ratio of the first diameter to the width is from 12 to 14.

11. The light-emitting device of claim 10, wherein, the central recessed surface has a third circular structure, the third circular structure has a third diameter, and the width is greater than the third diameter.

12. The light-emitting device of claim 5, wherein, the reflective surface is connected to the central recessed surface at a central peripheral portion, and the first curved portion has a curvature decreasing from a peripheral point of the central peripheral portion to the apex.

13. The light-emitting device of claim 12, wherein, the second curved portion has a curvature decreasing from the inflection point to the apex.

14. The light-emitting device of claim 13, wherein, the third curved portion has a curvature decreasing from the inflection point to the contact point.

15. The light-emitting device of claim 5, wherein, the third curved portion has a first curved segment and a second curved segment, and the light-emitting element overlaps the second curved segment without overlapping the first curved segment.

16. The light-emitting device of claim 15, wherein, the light has a fourth beam passing through the second curved segment.

17. The light-emitting device of claim 5, wherein, relative to a vertical axis passing through the apex to the substrate, the first curved portion is asymmetric with respect to the second curved portion.

18. The light-emitting device of claim 1, wherein, the recess depth is greater than the first height, and a ratio of the second height to the first height is between 7.8 and 10.
